(19) United States
(12) Patent Application Publication
(10) Pub. No.: US 2026/0101716 A1
(43) Pub. Date: Apr. 9, 2026

(54) SUBSTRATE GRIPPER

(71) Applicant: APPLIED MATERIALS, INC., Santa Clara, CA (US)

(72) Inventors: James Christopher Hansen, Mountain View, CA (US); Paul Benjamin Reuter, Austin, TX (US)

(21) Appl. No.: 19/046,831

(22) Filed: Feb. 6, 2025

Related U.S. Application Data
(60) Provisional application No. 63/702,731, filed on Oct. 3, 2024.

(51) Int. Cl. H01L 21/687; H01L 21/677

(52) U.S. Cl. CPC H10P 72/7602; H10P 72/3202; H10P 72/7624

(57) ABSTRACT

A substate gripper includes a first plate, a second plate, and a plurality of arms coupled with the first plate and the second plate. Each of the plurality of arms includes at least one flexure member configured to flex responsive to movement of the second plate with respect to the first plate. Flexure of the flexure members of the plurality of arms causes respective ends of the plurality of arms to perform a gripping action to grip a substrate.

### RELATED APPLICATION

This application claims the benefit of U.S. Provisional Ser. No. 63/702,731 filed Oct. 3, 2024, the entire contents of which are incorporated by reference herein.

### TECHNICAL FIELD

This instant specification generally relates to a gripping device for substrates (i.e., a substrate gripper). The instant disclosure relates specifically to a substrate gripper, and methods and systems related to the substrate gripper.

### BACKGROUND

Substrates are sometimes processed while supported on a substrate support. A substrate may be transported to and/or from a processing chamber while supported on the substrate support. The substrate support may make effectively gripping the substrates'edges difficult. Some substrates are sensitive to contact on a top surface. Separating the substrate from the substrate support, such as after processing, can be difficult. Similarly, assembling the substrate to the substrate support, such as before processing, can also be difficult.

### SUMMARY

In one embodiment, a substrate gripper includes a first plate, a second plate, and a plurality of arms coupled with the first plate and the second plate. Each of the plurality of arms includes at least one flexure member configured to flex responsive to movement of the second plate with respect to the first plate. Flexure of the flexure members of the plurality of arms causes respective ends of the plurality of arms to perform a gripping action to grip a substrate.

In one embodiment, a factory interface includes a substrate-handling robot and a substrate gripper. The substrate gripper includes a first plate, a second plate, and a plurality of arms coupled with the first plate and the second plate. Each of the plurality of arms includes at least one flexure member configured to flex responsive to movement of the second plate with respect to the first plate. Flexure of the flexure members of the plurality of arms causes respective ends of the plurality of arms to perform a gripping action to grip a substrate.

In one embodiment, a method includes providing, by a substrate-handling robot, a substrate support supporting a substrate to a substrate gripper. The method further includes actuating a plurality of arms of the substrate gripper. Each of the plurality of arms includes at least one flexure member configured to flex responsive to actuation of the plurality of arm. Flexure of the flexure members of the plurality of arms causes respective ends of the plurality of arms to perform a gripping action to grip the substrate. The method further includes separating the substrate from the substrate support by the substrate gripper.

### BRIEF DESCRIPTION OF THE DRAWINGS

Aspects and embodiments of the present disclosure will be understood more fully from the detailed description given below and from the accompanying drawings of various aspects and embodiments of the disclosure, which, however, should not be taken to limit the disclosure to the specific aspects or embodiments, but are for explanation and understanding only. The drawings, described below, are for illustrative purposes and are not necessarily drawn to scale.

FIG. 1 illustrates a schematic view of an example manufacturing system (e.g., a substrate processing system), in accordance with some embodiments of the present disclosure.

FIGS. 2A-2B illustrate example schematic views of a substrate gripper, in accordance with some embodiments of the present disclosure.

FIG. 2C illustrates a simplified perspective view of a substrate support, in accordance with some embodiments of the present disclosure.

FIGS. 3A-3E illustrate assembled and component views of a substrate gripper, in accordance with some embodiments of the present disclosure.

FIGS. 4A-4B illustrate schematic views of an arm of a substrate gripper, in accordance with some embodiments of the present disclosure.

FIG. 5 is a flow diagram of a method of using a substrate gripper, in accordance with some embodiments of the present disclosure.

### DETAILED DESCRIPTION

Semiconductor device manufacturing and other device manufacturing (e.g., such as for displays, photovoltaic devices, etc.) often involves tens and even hundreds of complex operations to implement raw substrate (e.g., wafer) preparation, polishing, material deposition, etching, and the like. Substrates that are delivered for processing in processing chambers can include bare substrates (e.g., silicon substrates, quartz substrates, Gallium Arsenide substrates, corundum substrates), substrates that have been preprocessed (e.g., covered with one or more films, such as carbon films), or substrates that have already undergone one or more processing operations (e.g., deposition, patterning, etching, and so on). In some embodiments, substrates are transported to and/or from a processing chamber while supported on a substrate support, such as a susceptor. The substrate is placed on the substrate support prior to processing and is removed from the substrate support after processing.

In some embodiments, a substrate support, such as a susceptor, includes a recessed pocket in which a substrate sits. The substrate support may include a raised rim surrounding the substrate. The top of the substrate may sit substantially flat with the rim of the substrate support, blocking the edges of the substrate. In some embodiments, a substrate gripper may grip the edges of the substrate. However, where the edges of the substrate are blocked, a conventional edge-grip cannot be used. Therefore, separating a substrate from a substrate support as described herein may prove difficult. Some previous solutions to the above-described problem include using vacuum handlers to lift substrates from substrate supports. However, vacuum handlers often stir up particles which then contaminate the substrate. Other solutions include contacting the top surface of a substrate. However, contacting the top surface of a substrate can damage the substrate. In instances where the structures and/or features formed on the top of the substrate are fragile, contacting the top surface of the substrate can contaminate the substrate and/or cause irreparable damage. In either instance, the substrate may be scrapped.

Aspects and embodiments of the present disclosure address the above-described problem and shortcomings of previous solutions by providing a substrate gripper configured to separate a substrate from a substrate support. In some embodiments, the substrate gripper described herein allows for minimal contact on a wafer edge and access to a wafer in a pocket of a substrate support (e.g., a susceptor, etc.) using a narrow channel (e.g., a gas channel) formed in the substrate support. In some embodiments, the substrate gripper is configured to be positioned above a substrate and to grip the substrate from above. In some embodiments, the substrate gripper described herein uses a compliant/flexure design of gripper arms to eliminate relative motion of sliding and/or rotating joints to significantly reduce the amount of generated particles. Moreover, the compliant/flexure design of the arms enables repeatable motions with a single linear input actuation. Furthermore, the substrate gripper described herein may have few components which are simple to manufacture.

In some embodiments, a substrate gripper includes a plurality of arms (e.g., three or more arms). Each of the plurality of arms are coupled with a first plate and a second plate. The first and second plates may be arranged one above the other. In some embodiments, the first and second plates form a central hub from which the arms radiate. Either one of the first plate or the second plate is coupled with a mounting member. The mounting member may be a frame member to give structure to the substrate gripper. The first plate or the second plate may be coupled with the mounting member directly or indirectly, such as by one or more brackets, etc.

In some embodiments, each of the plurality of arms includes at least one flexure member that is configured to flex responsive to movement of the second plate with respect to the first plate. Flexure of the flexure members causes respective ends of the plurality of arms to perform a gripping action, such as for picking a substrate from a substrate support. In some embodiments, the at least one flexure member elastically deforms without yielding responsive to movement of the second plate with respect to the first plate. In some embodiments, the respective ends of the plurality of arms have a motion that includes an arc motion when actuated. The arc motion includes a horizontal movement that is orthogonal to the movement of the second plate with respect to the first plate.

In some embodiments, an actuator (e.g., a linear actuator, etc.) causes the second plate to move with respect to the first plate to cause the plurality of arms to actuate. Actuation of the arms may cause the ends of the arms to grip a substrate. In some embodiments, gripping members coupled with a respective end of an arm of the plurality of arms are to contact the edges of the substrate. Each of the gripping members may be configured to pass through a gas vent of a substrate support to grip an edge of the substrate. By passing through the gas vent, the edges of the substrate can be accessed for gripping by the gripping members.

Aspects and embodiments of the present disclosure may result in technological advances. For example, the substrate gripper described herein is capable of separating a substrate from a substrate support without contacting the top surface of the substrate and without using vacuum that can stir up particles. In another example, the substrate gripper described herein has fewer moving parts when compared to conventional substrate grippers, reducing the amount of particles that may be generated. Moreover, the substrate gripper described herein can be easily and cheaply made using common manufacturing techniques. Therefore, the substrate gripper described herein can reduce substrate defects and scrap rate, while reducing upfront costs for implementation in a substrate processing facility.

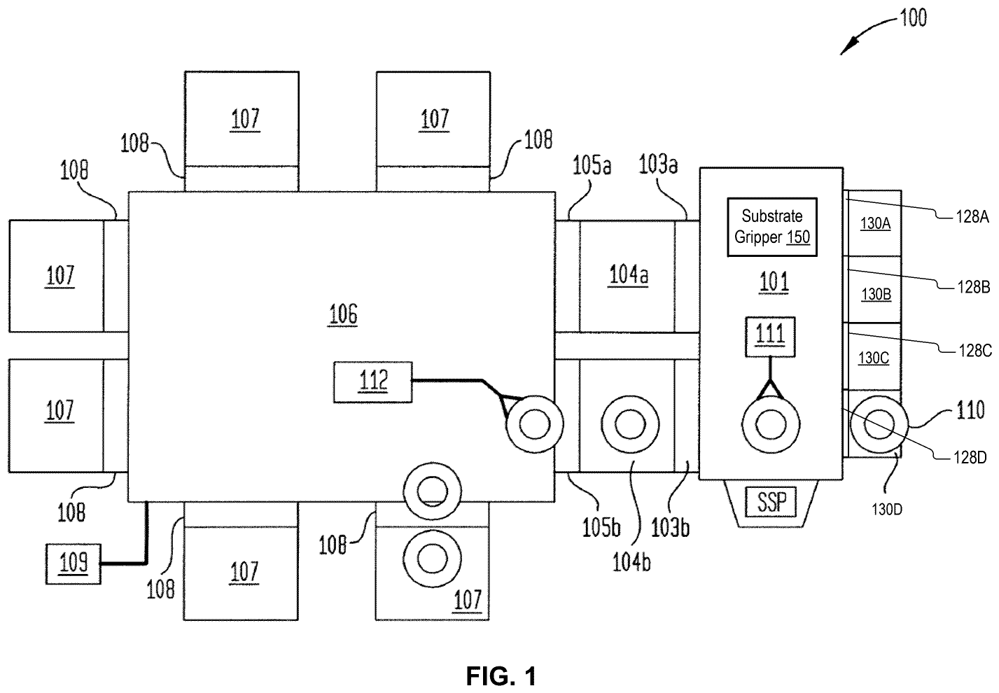

FIG. 1 illustrates a schematic view of an example manufacturing system 100 (e.g., a substrate processing system), in accordance with some embodiments of the present disclosure. The manufacturing system 100 includes a factory interface (FI) 101 and load ports 128x (e.g., load ports 128A-D). In some embodiments, the load ports 128A-D are directly mounted to (e.g., sealed against) FI 101. Enclosure systems 130x (e.g., cassette, FOUP, process kit enclosure system, or the like) are configured to removably couple (e.g., dock) to the load ports 128A-D. In some embodiments, enclosure system 130A is coupled to load port 128A, enclosure system 130B is coupled to load port 128B, enclosure system 130C is coupled to load port 128C, and enclosure system 130D is coupled to load port 128D. In some embodiments, one or more enclosure systems 130x are coupled to the load ports 128x for transferring substrates and/or other items into and out of the processing manufacturing system 100. Each of the enclosure systems 130x may seal against a respective load port 128x. In some embodiments, a first enclosure system 130A is docked to a load port 128A. Once such operation or operations are performed, the first enclosure system 130A is undocked from the load port 128A, and then a second enclosure system 130x (e.g., a FOUP containing substrate(s)) is docked to the same load port 128A. In some embodiments, an enclosure system 130x (e.g., enclosure system 130A) is a system for performing a calibration operation or a diagnostic operation.

In some embodiments, a load port 128x includes a front interface that forms an opening. The load port 128x additionally includes a horizontal surface for supporting an enclosure system 130x. Each enclosure system 130x has a front interface that forms a vertical opening. The front interface of the enclosure system 130x is sized to interface with (e.g., seal to) the front interface of the load port 128x (e.g., the vertical opening of the enclosure system 130x is approximately the same size as the vertical opening of the load port 128x). The enclosure system 130x is placed on the horizontal surface of the load port 128x and the vertical opening of the enclosure system 130x aligns with the vertical opening of the load port 128x. The front interface of the enclosure system 130x interconnects with (e.g., clamp to, be secured to, be sealed to) the front interface of the load port 128x. A bottom plate (e.g., base plate) of the enclosure system 130x has features (e.g., load features, such as recesses or receptacles, that engage with load port kinematic pin features, a load port feature for pin clearance, and/or an enclosure system docking tray latch clamping feature) that engage with the horizontal surface of the load port 128x. The same load ports 128x that are used for different types of enclosure systems 130x.

In some embodiments, the manufacturing system 100 also includes first vacuum ports 103a, 103b coupling FI 101 to respective degassing chambers 104a, 104b. Second vacuum ports 105a, 105b are coupled to respective degassing chambers 104a, 104b and disposed between the degassing chambers 104a, 104b and a transfer chamber 106 to facilitate transfer of substrates and other content 110 (e.g., substrate supports such as susceptors, etc.) into the transfer chamber 106. In some embodiments, a manufacturing system 100 includes and/or uses one or more degassing chambers 104 and a corresponding number of vacuum ports 103, 105 (e.g., a manufacturing system 100 includes a single degassing chamber 104, a single first vacuum port 103, and a single second vacuum port 105). The transfer chamber 106 includes a plurality of processing chambers 107 (e.g., four processing chambers 107, six processing chambers 107, etc.) disposed therearound and coupled thereto. The processing chambers 107 are coupled to the transfer chamber 106 through respective ports 108, such as slit valves or the like. In some embodiments, FI 101 is at a higher pressure (e.g., atmospheric pressure) and the transfer chamber 106 is at a lower pressure (e.g., vacuum). Each degassing chamber 104 (e.g., load lock, pressure chamber) has a first door (e.g., first vacuum port 103) to seal the degassing chamber 104 from FI 101 and a second door (e.g., second vacuum port 105) to seal the degassing chamber 104 from the transfer chamber 106. Content is to be transferred from FI 101 into a degassing chamber 104 while the first door is open and the second door is closed, the first door is to close, the pressure in the degassing chamber 104 is to be reduced to match the transfer chamber 106, the second door is to open, and the content is to be transferred out of the degassing chamber 104. A local center finding (LCF) device is to be used to align the content in the transfer chamber 106 (e.g., before entering a processing chamber 107, after leaving the processing chamber 107).

In some embodiments, the processing chambers 107 includes or more of etch chambers, deposition chambers (including atomic layer deposition, chemical vapor deposition, physical vapor deposition, or plasma enhanced versions thereof), anneal chambers, or the like.

Factory interface 101 includes a factory interface robot 111. Factory interface robot 111 includes a robot arm, such as a selective compliance assembly robot arm (SCARA) robot. Examples of a SCARA robot include a 2 link SCARA robot, a 3 link SCARA robot, a 4 link SCARA robot, and so on. The factory interface robot 111 includes an end effector on an end of the robot arm. The end effector is configured to pick up and handle specific objects, such as wafers. Alternatively, or additionally, the end effector is configured to handle objects such as a substrate support (e.g., a susceptor), which may or may not have a wafer disposed thereon. Accordingly, in some embodiments, substrate supports and supported wafers (or other substrates) may be transferred together by the robot arm. The robot arm has one or more links or members (e.g., wrist member, upper arm member, forearm member, etc.) that are configured to be moved to move the end effector in different orientations and to different locations.

The factory interface robot 111 is configured to transfer objects (e.g., substrates, substrate supports, or combinations thereof) between enclosure systems 130x (e.g., cassettes, FOUPs) and degassing chambers 104a, 104b (or load ports). The factory interface robot 111 is taught a fixed location relative to a load port 128x using the enclosure system 130x in embodiments. The fixed location in one embodiment corresponds to a center location of an enclosure system 130A placed at a particular load port 128x, which in embodiments also corresponds to a center location of an enclosure system 130B placed at the particular load port 128x. Alternatively, the fixed location may correspond to other fixed locations within the enclosure system 130x, such as a front or back of the enclosure system 130x. The factory interface robot 111 is calibrated using the enclosure system 130x in some embodiments. The factory interface robot 111 is diagnosed using the enclosure system 130x in some embodiments.

In some embodiments, factory interface 101 includes a substrate gripper 150. The substrate gripper 150 may be fixed within the factory interface 101. Alternatively, the substrate gripper 150 may be coupled to the end of a robot within the factory interface 101. The substrate gripper 150 may include a plurality of arms having flexure members as described herein. In some embodiments, the factory interface robot 111 is configured to provide a substrate supported on a substrate support (e.g., a susceptor) to the substrate gripper 150. The substrate gripper 150 may be positioned above the substrate when the substrate supported on the substrate support is provided to the substrate gripper 150. The substrate gripper arms may be actuated to perform a gripping motion. In some embodiments, the ends of the arms make an arc motion when actuated and may grip the substrate from above to separate the substrate from the substrate support. In some embodiments, the factory interface robot 111 transports the substrate support to one of the enclosure systems 130x separate from the substrate while the substrate gripper 150 holds (e.g., grips) the substrate. The factory interface robot 111 may retrieve the substrate from the substrate gripper 150 and transport the substrate to another one of the enclosure systems 130x separate from the substrate support.

In embodiments, the substrate gripper 150 may be used to place substrates on substrate supports and/or to remove substrates from substrate supports. A substrate support with a supported substrate may be moved to the substrate gripper 150, which may remove the substrate from the substrate support. Similarly, a substrate may be moved to the substrate gripper 150. The substrate gripper 150 may grip the substrate, lifting the substrate from a robot arm 111. The robot arm (or another robot arm) may then move a substrate support to the substrate gripper 150, and the substrate gripper 150 may release the substrate onto the substrate support, after which the robot arm 111 may move the substrate support and substrate together (e.g., to a load lock 104a, 104b for transfer to a process chamber and processing therein).

Transfer chamber 106 includes a transfer chamber robot 112. Transfer chamber robot 112 includes a robot arm with an end effector at an end of the robot arm. The end effector is configured to handle particular objects, such as wafers. In some embodiments, the transfer chamber robot 112 is a SCARA robot, but may have fewer links and/or fewer degrees of freedom than the factory interface robot 111 in some embodiments.

A controller 109 controls various aspects of the manufacturing system 100. The controller 109 is and/or includes a computing device such as a personal computer, a server computer, a programmable logic controller (PLC), a microcontroller, and so on. The controller 109 includes one or more processing devices, which, in some embodiments, are general-purpose processing devices such as a microprocessor, central processing unit, or the like. More particularly, in some embodiments, the processing device is a complex instruction set computing (CISC) microprocessor, reduced instruction set computing (RISC) microprocessor, very long instruction word (VLIW) microprocessor, or a processor implementing other instruction sets or processors implementing a combination of instruction sets. In some embodiments, the processing device is one or more special-purpose processing devices such as an application specific integrated circuit (ASIC), a field programmable gate array (FPGA), a digital signal processor (DSP), network processor, or the like. In some embodiments, the controller 109 includes a data storage device (e.g., one or more disk drives and/or solid state drives), a main memory, a static memory, a network interface, and/or other components. In some embodiments, the controller 109 executes instructions to perform any one or more of the methods or processes described herein. The instructions are stored on a computer readable storage medium, which include one or more of the main memory, static memory, secondary storage and/or processing device (during execution of the instructions). The controller 109 receives signals from and sends controls to factory interface robot 111 and wafer transfer chamber robot 112 in some embodiments.

According to one aspect of the disclosure, to transfer content 110 (e.g., a substrate) into a processing chamber 107, the content 110 is removed from an enclosure system 130B via factory interface robot 111 located in FI 101. The factory interface robot 111 and/or substrate gripper 150 may place the content 110 on a support (e.g., a substrate support, a susceptor, etc.) and transfers the content 110 through one of the first vacuum ports 103a, 103b and into a respective degassing chamber 104a, 104b. A transfer chamber robot 112 located in the transfer chamber 106 removes the content 110 from one of the degassing chambers 104a, 104b through a second vacuum port 105a or 105b. The transfer chamber robot 112 moves the content 110 into the transfer chamber 106, where the content 110 is transferred to a processing chamber 107 through a respective port 108. After processing, the processed content 110 (e.g., a substrate supported on a substrate support and/or susceptor, etc.) is removed from the manufacturing system 100 in reverse of any manner described herein.

The manufacturing system 100 includes chambers, such as FI 101 (e.g., equipment front end module, EFEM) and adjacent chambers (e.g., load port 128x, enclosure system 130x, SSP, degassing chamber 104 (such as a loadlock chamber), or the like) that are adjacent to FI 101. Some or all of the chambers can be sealed. In some embodiments, inert gas (e.g., one or more of nitrogen, argon, neon, helium, krypton, or xenon) is provided into one or more of the chambers (e.g., FI 101 and/or adjacent chambers) to provide one or more inert environments. In some examples, FI 101 is an inert EFEM that maintains the inert environment (e.g., inert EFEM minienvironment) within FI 101 so that users do not need to enter FI 101 (e.g., the manufacturing system 100 is configured for no manual access within FI 101).

In some embodiments, gas flow (e.g., inert gas, nitrogen) is provided into one or more chambers (e.g., FI 101) of the manufacturing system 100. In some embodiments, the gas flow is greater than leakage through the one or more chambers to maintain a positive pressure within the one or more chambers. In some embodiments, the inert gas within FI 101 is recirculated. In some embodiments, a portion of the inert gas is exhausted. In some embodiments, the gas flow of non-recirculated gas into FI 101 is greater than the exhausted gas flow and the gas leakage to maintain a positive pressure of inert gas within FI 101. In some embodiments, FI 101 is coupled to one or more valves and/or pumps to provide the gas flow into and out of FI 101. A processing device (e.g., of controller 109) controls the gas flow into and out of FI 101. In some embodiments, the processing device receives sensor data from one or more sensors (e.g., oxygen sensor, moisture sensor, motion sensor, door actuation sensor, temperature sensor, pressure sensor, etc.) and determines, based on the sensor data, the flow rate of inert gas flowing into and/or out of FI 101.

The enclosure system 130x seals to the load port 128x responsive to being docked on the load port 128x. The enclosure system 130x provides purge port access so that the interior of the enclosure system 130x can be purged prior to opening the enclosure system 130x to minimize disturbance of the inert environment within FI 101.

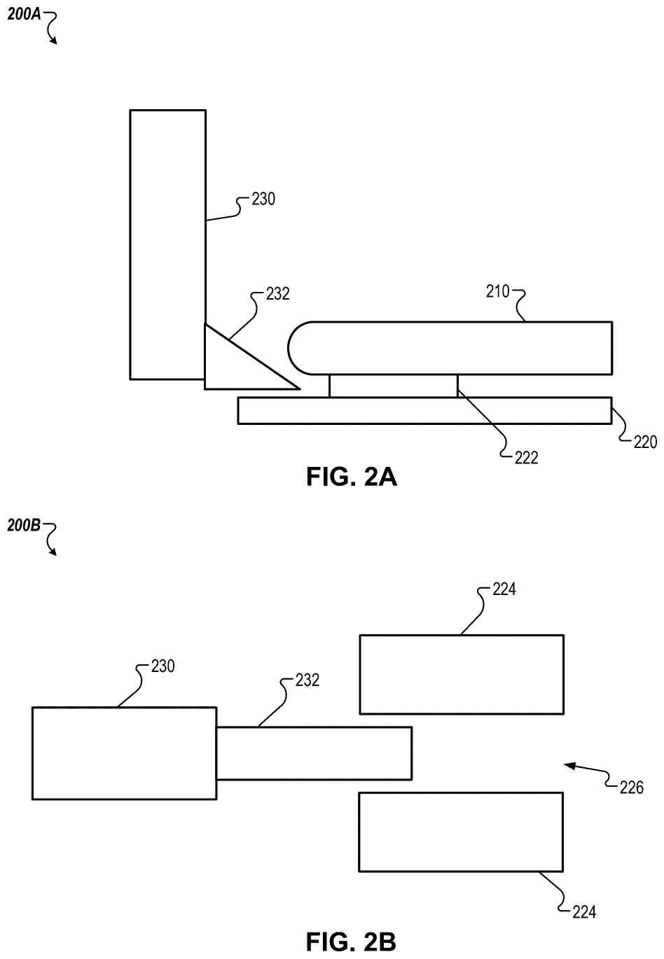

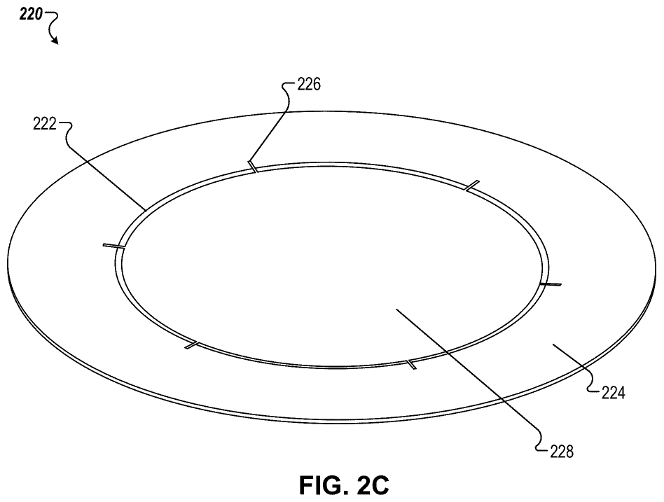

FIGS. 2A-2B illustrate example schematic views of a substrate gripper, in accordance with some embodiments of the present disclosure. Referring to FIG. 2A, a schematic side view of a substrate gripper, substrate, and substrate support is shown. Referring to FIG. 2B, a schematic top-down view of a substrate gripper and substrate support is shown. In some embodiments, a gripping member 232 is coupled at the end of a gripper arm 230. Upon actuation of the arm 230, the gripping member 232 may contact the edge and/or bottom of substrate 210. In some embodiments, gripping member 232 grips a bottom bevel edge of substrate 210 when arm 230 is actuated. Gripping member 232 may be a wedge-shaped member but can have other shapes in some embodiments. In some embodiments, gripping member 232 may be made of an engineering polymer such as polyether ether ketone (PEEK). The gripping member 232 may be made of a material that does not shed particles and may not scratch the substrate 210. In some embodiments, the gripping member 232 is made from a sheet of thermoplastic, such as by laser cutting. In alternative embodiments, the gripping member 232 is made of a ceramic such as quartz or alumina, etc.

The substrate 210 may sit on a shelf 222 of a susceptor 220 within a recessed pocket. Susceptor 220 may be a substrate support. In some embodiments, the susceptor 220 has a raised rim 224. Rim 224 may not be illustrated in FIG. 2A but is illustrated in FIGS. 2B and 2C. In some embodiments, the rim 224 forms a pocket (pocket 228 illustrated in FIG. 2C) in which the substrate 210 may sit. The shelf 222 may extend circumferentially around the pocket. The rim 224 may form a plurality of channels 226. The channels 226 may be slots formed in the susceptor 220. The channels 226 may be for venting the region beneath the substrate 210 such as during a degassing operation, etc. When arm 230 is actuated, the gripping member 232 may pass through the channel 226 to grip the edge of the substrate 210. The susceptor 220 may then be lowered (e.g., by a substrate-handling robot, etc.) and the substrate 210 separated from the susceptor 220.

FIG. 2C illustrates a simplified perspective view of a substrate support (e.g., susceptor 220), in accordance with some embodiments of the present disclosure. In some embodiments, as described herein above, the susceptor forms a pocket 228. The pocket 228 may be a recess surrounded by a rim 224. A shelf 222 may extend circumferentially around the pocket 228. The shelf 222 may be disposed within the pocket 228 proximate a circumferential edge of the pocket 228. In some embodiments, a substrate (not illustrated in FIG. 2C) may be disposed within the pocket 228, supported on the shelf 222. When a substrate is disposed within the pocket 228, the top surface of the substrate may be substantially flush with the top surface of rim 224. In some embodiments, rim 224 forms channels 226. The channels 226 may extend through the shelf 222. In some embodiments, gripping members (not illustrated) may pass through the channels 226 to grip the edge of a substrate within the pocket 228. In some embodiments, the channels 226 have a width less than approximately one millimeter. The gripping members (i.e., gripping members 232) may have a width less than the width of the channels 226. For example, the width of a gripping member may be less than one millimeter.

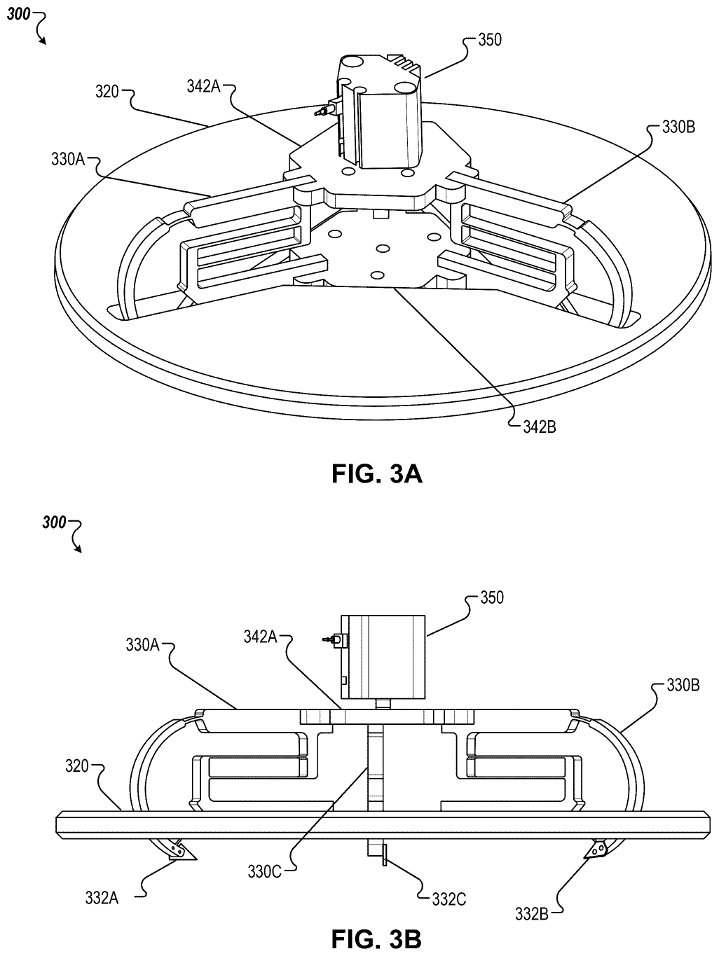

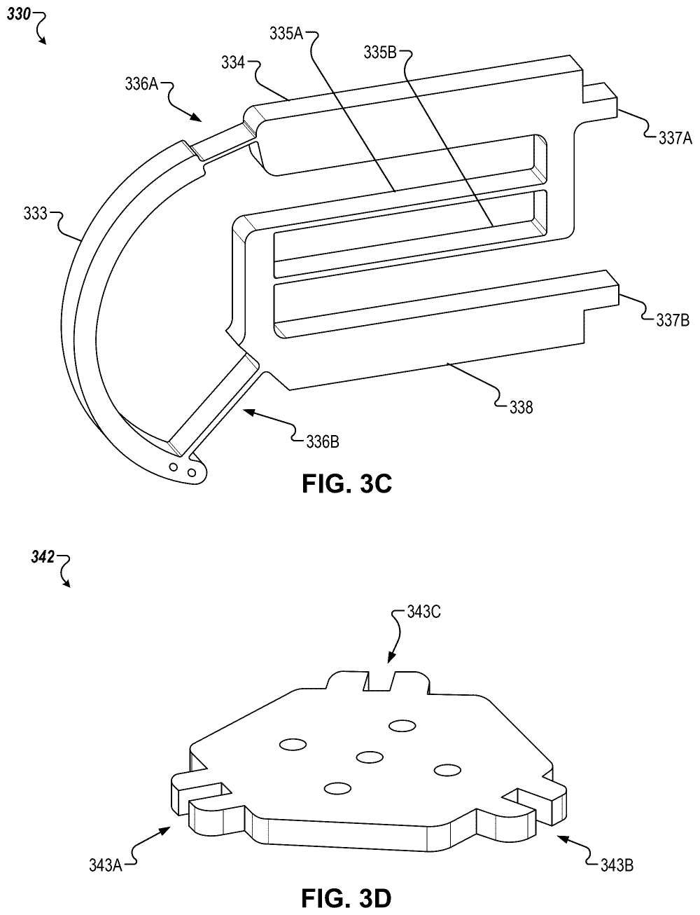

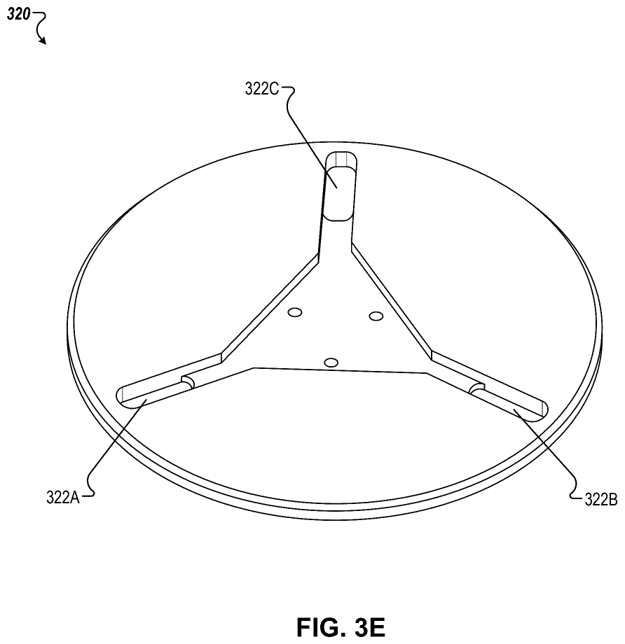

FIGS. 3A-3E illustrate assembled and component views of a substrate gripper, in accordance with some embodiments of the present disclosure. Referring to FIGS. 3A and 3B, perspective and side views of a substrate gripper 300 are shown. In some embodiments, substrate gripper 300 includes multiple arms 330. For example, and in some embodiments, substrate gripper 300 includes arms 330A-330C. Each of the arms 330 are coupled with a first plate 342A and a second plate 342B. In some embodiments, the arms 330 are bonded to the plates 342, such as with an adhesive or by a welded joint (e.g., a laser welded joint, an ultrasonic welded joint, etc.). The plates 342 may be a central hub from which the arms 330 are arranged radially. In some embodiments, one of the plates 342 is rigidly coupled with a shield 320. For example, as illustrated in FIGS. 3A and 3B, lower plate 342B is coupled with shield 320 and upper plate 342A is left uncoupled from the shield 320. In an alternative example, upper plate 342A may be coupled with shield 320 (such as by one or more brackets, etc.) and lower plate 342B may be left uncoupled from the shield 320. The shield 320 may be a mounting member for mounting one of the plates 342 and/or an actuator 350.

Shield 320 may be a circular plate having features for coupling plates 342 and/or through which arms 330 can pass. More details regarding shield 320 are shown and discussed with respect to FIG. 3E. In some embodiments, substrate gripper 300 is to be disposed above a substrate and may grip the substrate from above. The ends of arms 330 may pass through features of shield 320 (e.g., from a top side to a bottom side of the shield 320). In some embodiments, gripping members 332 are coupled at the ends of arms 330. For example, a gripping member 332A is coupled at the end of arm 330A, gripping member 332B is coupled at the end of arm 330B, and gripping member 332C is coupled at the end of arm 330C. In some embodiments, the gripping members 332 are coupled with the end of the respective arm 330 by a bonded joint and/or by a welded joint, etc. The gripping members 332 may grip the edge of a substrate when arms 330 are actuated.

Substrate gripper 300 may include an actuator 350. In some embodiments, actuator 350 is a pneumatic actuator. Alternatively, actuator 350 can be an electro-mechanical actuator, etc. Actuator 350 may be a linear actuator. In some embodiments, substrate gripper 300 includes a manual actuator. For example, substrate gripper 300 can include a handle having a lever or button, etc. that can be manually actuated by a user (e.g., a technician, etc.) for manually causing the substrate gripper 300 to grip a substrate. In some embodiments, actuator 350 is coupled with plate 342A and plate 342B. A stationary portion of actuator 350 may be coupled with one plate while a movable portion of actuator 350 may be coupled with the other plate. In some embodiments, when actuator 350 actuates, one of the plates 342 is caused to move relative to the other of the plates 342. For example, actuation of actuator 350 may cause plate 342A to move downward with respect to plate 342B. In another example, actuation of actuator 350 may cause plate 342B to move upward with respect to plate 342A. In some embodiments, a single actuator 350 causes all of the arms 330 to actuate (e.g., to grip a substrate, etc.).

In some embodiments, actuator 350 causes arms 330 to actuate, such as to grip a substrate. Movement of plates 342 with respect to one another (e.g., upward or downward, etc.) may cause arms 330 to actuate. In some embodiments, each of the arms 330 include at least one flexure member. In some embodiments, each of the arms 330 include at least one portion that is compliant. For example, each of the arms 330 include a member and/or portion that can bend without yielding. Actuation of the arms 330 (e.g., caused by the actuator 350 and movement of the plates 342, etc.) cause flexing of the flexure members. Flexure of the flexure members may cause the ends of the arms 330 to perform a gripping action, such as to grip a substrate. In some embodiments, when arms 330 are actuated, the ends of the arms 330 (having gripping members 332 coupled thereto) move in an arcing motion. The arcing motion may include motion in a vertical plane. In some embodiments, the arcing motion of the arms 330 includes horizontal movement that is orthogonal to the movement of plate 342A with respect to plate 342B. For example, movement of plate 342A downwards with respect to plate 342B may cause flexure members of arms 330 to flex, which in turn may cause the ends of the arms 330 to move horizontally inwards toward the center of the substrate gripper 300. The horizontal movement of the ends of arms 330 may be within a vertical plane. In some embodiments, the arcing motion includes an inward motion and an upward motion.

Referring to FIG. 3C, a perspective view of an arm 330 is shown. In some embodiments, arm 330 is made up of multiple members, such as flexure members and non-flexure members. In some embodiments, arm 330 includes an upper member 334 and a lower member 338. The upper member 334 includes an upper coupler 337A for coupling to a plate 342 (e.g., upper plate 342A) and the lower member 338 includes a lower couple 337B for coupling to a plate 342 (e.g., lower plate 342B). The upper member 334 and the lower member 338 may be coupled to one another by at least two parallel flexure members 335A and 335B. In some embodiments, the parallel flexure members 335A and 335B are configured to flex responsive to upper member 334 and lower member 338 becoming closer to one another. For example, actuation of an arm 330 (e.g., such as by actuator 350 and via the plates coupled to the upper and lower couplers 337) may cause the upper member 334 to move downward toward lower member 338. The parallel flexure members 335A and 335B may flex to allow the upper member 334 to move downward toward lower member 338. In some embodiments, the parallel flexure members 335A and 335B remain substantially parallel to one another during the actuation. In some embodiments, the upper member 334 and the lower member 338 are held substantially parallel by the parallel flexure members 335A and 335B. In some embodiments, upper member 334 and lower member 338 substantially don't flex upon actuation of the arm 330.

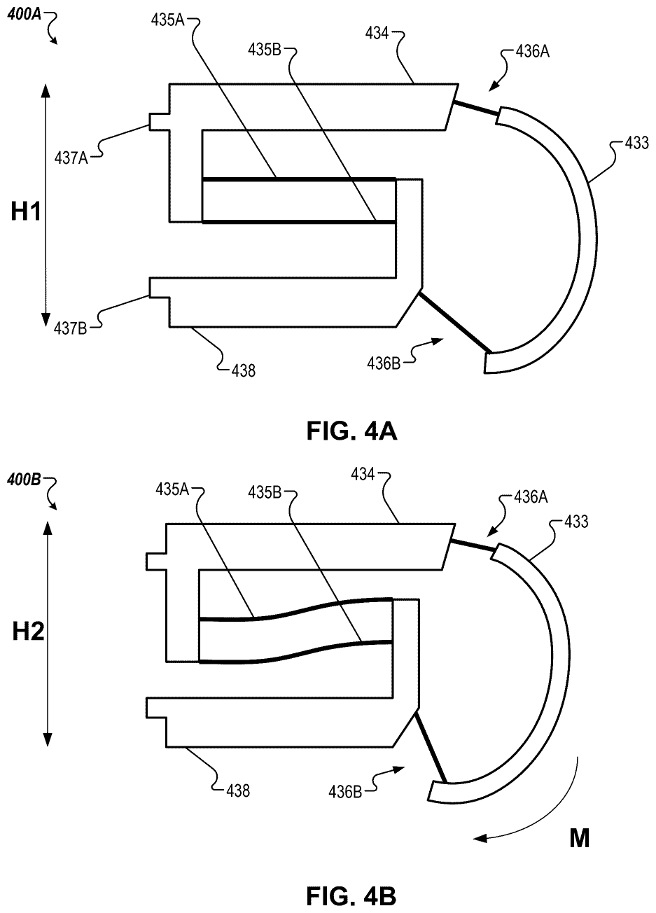

In some embodiments, arm 330 includes a distal member 333. The distal member 333 may include an end upon which a gripping member can be coupled. For example, a gripping member can be coupled to the lower end of the distal member 333 for gripping a substrate when the arm 330 is actuated. In some embodiments, the distal member 333 is coupled with the upper member 334 by an upper flexure member 336A and coupled with the lower member 338 by a lower flexure member 336B. In some embodiments, upon actuation of the arm 330, the upper flexure member 336A and the lower flexure member 336B may flex to cause the lower end of the distal member 333 to make an arc motion. In some embodiments, when upper member 334 and lower member 338 are caused to move toward one another, the upper flexure member 336A and the lower flexure member 336B flex to cause the lower end of the distal member 333 to make an arc motion. A gripping member coupled with the lower end of the distal member 333 may grip a substrate edge when the arm 330 is actuated. More details regarding the actuation of arm 330 are discussed and illustrated herein with respect to FIGS. 4A and 4B.

In some embodiments, arm 330 is made of a plastic such as polylactic acid, polypropylene, or polyethylene (e.g., high-density polyethylene, etc.). In some embodiments arm 330 is made of a thermoplastic. In other embodiment, arm 330 is made of a metal such as aluminum, etc. In some embodiments, arm 330 is made from an extrusion, is made by performing a machining process (e.g., wire electro-discharge machining, etc.), or is made by a cutting process (e.g., laser cutting, etc.). In some embodiments, the strain of the flexure members can be tuned by selecting a material with material properties (such as a stress-strain curve, etc.) that will provide the desired motion for the lower end of the distal member 333. Similarly, the thicknesses of the flexure members can be tuned for the desired motion. In some embodiments, a wider range of motion can be achieved by thinning the flexure members and/or by selecting a material that is more flexible without yielding.

Referring to FIG. 3D, a perspective view of a plate 342 is shown. Plate 342 may have a substantially hexagonal profile. Plate 342 may include one or more mounting holes for coupling the plate 342 to a shield 320 and/or to one or more brackets. In some embodiments, plate 342 forms slots 343 for coupling a plurality of arms 330. For example, and in some embodiments, plate 342 includes a slot 343A for coupling a first arm 330, a slot 343B for coupling a second arm 330, and a slot 343C for coupling a third arm 330. In some embodiments, each of the slots 343 are formed by two protrusions protruding from the edge of plate 342, the slots 343 formed between the protrusions. In some embodiments, plate 342 is made of a plastic such as polylactic acid, polypropylene, or polyethylene (e.g., high-density polyethylene, etc.). In some embodiments arm 330 is made of a thermoplastic. In other embodiment, plate 342 is made of a metal such as aluminum, etc. In some embodiments, arms 330 are coupled with the plate 342 by a bonded joint. In some embodiments, arms 330 are coupled with the plate 342 by a welded joint. In some embodiments, three arms 330 can be coupled with plate 342. However, it may be possible to couple more or less than three arms 330 to plate 342 in some embodiments.

Referring to FIG. 3E, a perspective view of a shield 320 is shown. In some embodiments, shield 320 forms a substantially circular body. Shield 320 may form one or more mounting holes, such as for coupling a plate 342 and/or for coupling one or more brackets (the one or more brackets for coupling a plate 342 to the shield, etc.). Shield 320 may be a mounting member for mounting a plate 342. In some embodiments, shield 320 forms a recess into which a plate 342 can be coupled. In some embodiments, shield 320 forms multiple slots 322 through which the ends of arms 330 can pass. For example, and in some embodiments, shield 320 forms a first slot 322A through which the end of a first arm 330 can pass, a second slot 322B through which the end of a second arm 330 can pass, and a third slot 322C through which the end of a third arm 330 can pass. In some embodiments, shield 320 is configured to catch particles to prevent the particles from falling onto a substrate. For example, particles generated by an actuator above the shield 320 (or other particles, etc.) may fall onto the shield 320 rather than onto a substrate gripped by the substrate gripper beneath the shield 320. Some particles may fall through the slots 322, but such particles may not land on a gripped substrate but may instead land on the rim of a substrate support (e.g., the rim of a susceptor, etc.).

FIGS. 4A-4B illustrate schematic views of an arm of a substrate gripper, in accordance with some embodiments of the present disclosure. FIG. 4A shows an arm in a first unflexed state 400A. FIG. 4B shows an arm in a second flexed state 400B. In some embodiments, an upper member 434 and a lower member 438 are coupled by at least two parallel flexure members 435A and 435B. The parallel flexure member 435A and 435B may be thin members that can flex without yielding. When the upper member 434 and the lower member 438 are caused to be moved closer to one another (e.g., when the arm is actuated, etc.), such as by movement of mounting plates coupled with couplers 437A and 437B, the parallel flexure members 435A and 435B may flex (as shown in FIG. 4B). The parallel flexure members 435A and 435B may flex without yielding. In some embodiments, the parallel flexure members 435A and 435B cause the upper member 434 and the lower member 438 to be held and to move parallel to one another without twisting and/or rotating with respect to one another, etc. In some embodiments, the parallel flexure members 435A and 435B return to their unflexed state (shown in FIG. 4A) when the arm is de-actuated. In some embodiments, the arm has a first height H1 when in the non-actuated state (i.e., unactuated state, etc.) and the arm has a second height H2 when in the actuated state. H1 may be greater than H2.

In some embodiments, a distal member 433 is coupled to the upper member 434 by upper flexure member 436A and to lower member 438 by lower flexure member 436B. When the upper member 434 and the lower member 438 are caused to be moved closer to one another (e.g., when the arm is actuated, etc.), such as by movement of mounting plates coupled with couplers 437A and 437B, the upper flexure member 436A and the lower flexure member 436B may flex to cause the lower end of the distal member 433 to move with an arc motion M. The upper flexure member 436A and the lower flexure member 436B may flex without yielding. In some embodiments, a gripping member coupled to the lower end of the distal member 433 may grip a substrate when the distal member 433 moves. The arc motion M of the lower end of the distal member 433 may include a horizontal movement that is orthogonal to the movement of the upper member 434 and the lower member 438 with respect to one another. In some embodiments, the upper flexure member 436A and the lower flexure member 436B return to their unflexed state (shown in FIG. 4A) when the arm is de-actuated.

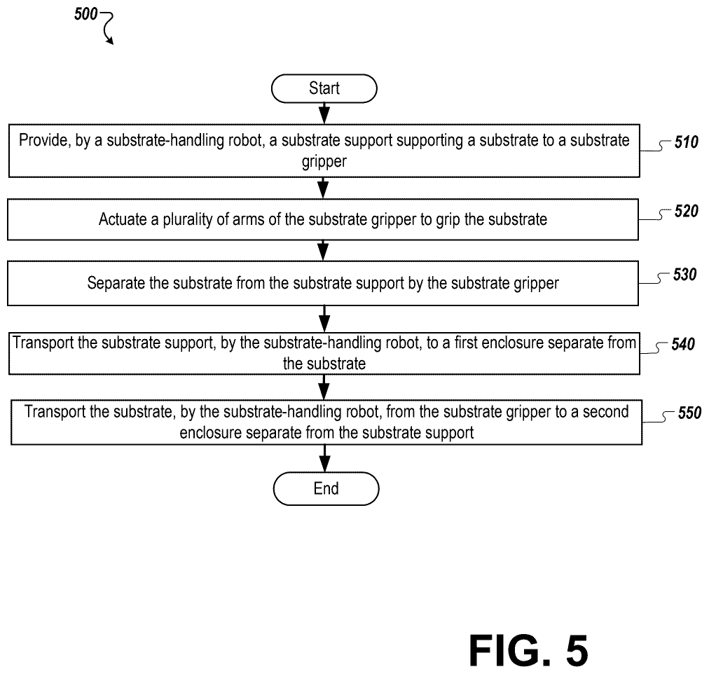

FIG. 5 is a flow diagram of a method 500 of using a substrate gripper, in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 510, a substrate support supporting a substrate is provided to a substrate gripper. The substrate supported by the substrate support may be provided to the substrate gripper by a substrate-handling robot. The substrate support may be a susceptor as described herein. In some embodiments, the substrate-handling robot and the substrate gripper are disposed within a factory interface of a substrate processing system.

At block 520, a plurality of arms of the substrate gripper are actuated to grip the substrate. In some embodiments, each of the plurality of arms includes at least one flexure member configured to flex responsive to actuation of the arms. Flexure of the flexure members causes respective ends of the arms to perform a gripping action to grip the substrate. In some embodiments, a gripping member coupled with the ends of each of the arms passes through a gas vent formed in the substrate support to grip the edge of the substrate.

At block 530, the substrate is separated from the substrate support by the substrate gripper. In some embodiments, the substrate gripper holds the substrate while the substrate support is lowered away from the substrate, the substrate gripper remaining stationary. In some embodiments, the substrate gripper holds the substrate and is lifted away from the substrate support while the substrate support remains stationary.

At block 540, the substrate support is transported to a first enclosure (e.g., a FOUP, etc.) separate from the substrate. The substrate support may be transported to the first enclosure by the substrate-handling robot. The first enclosure may be docked to the factory interface.

At block 550, the substrate is transported from the substrate gripper to a second enclosure separate from the substrate support. The substrate may be transported to the second enclosure by the substrate-handling robot. The second enclosure may be docked to the factory interface. In some embodiments, the substrate-handling robot retrieves the substrate from the substrate gripper. The substrate gripper may de-actuate the arms to un-grip the substrate, allowing transfer of the substrate from the substrate gripper to the substrate-handling robot.

It should be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

The embodiments of methods, hardware, software, firmware or code set forth above may be implemented via instructions or code stored on a machine-accessible, machine readable, computer accessible, or computer readable medium which are executable by a processing element. “Memory” includes any mechanism that provides (i.e., stores and/or transmits) information in a form readable by a machine, such as a computer or electronic system. For example, “memory” includes random-access memory (RAM), such as static RAM (SRAM) or dynamic RAM (DRAM); ROM; magnetic or optical storage medium; flash memory devices; electrical storage devices; optical storage devices; acoustical storage devices, and any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplary language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. Also, the terms “first,” “second,” “third,” “fourth,” etc. as used herein are meant as labels to distinguish among different elements and may not necessarily have an ordinal meaning according to their numerical designation.

What is claimed is:

1. A substrate gripper, comprising:
a first plate;
a second plate; and
a plurality of arms coupled with the first plate and the second plate, wherein each of the plurality of arms comprises at least one flexure member configured to flex responsive to movement of the second plate with respect to the first plate;
wherein flexure of the flexure members of the plurality of arms causes respective ends of the plurality of arms to perform a gripping action to grip a substrate.

2. The substrate gripper of claim 1, further comprising:
a plurality of gripping members, wherein each of the plurality of gripping members is coupled with a respective end of an arm of the plurality of arms, and wherein each of the plurality of gripping members is configured to grip an edge of the substrate.

3. The substrate gripper of claim 2, wherein each of the plurality of gripping members is configured to pass through a slot formed in a substrate support that supports the substrate to grip the edge of the substrate.

4. The substrate gripper of claim 1, further comprising:
an actuator configured to actuate to cause the movement of the second plate with respect to the first plate.

5. The substrate gripper of claim 1, wherein each of the plurality of arms comprises a distal member, an upper member, and a lower member, and wherein the distal member is coupled with at least one of the upper member or the lower member by the at least one flexure member.

6. The substrate gripper of claim 5, wherein the upper member is coupled to the lower member by at least two parallel flexure members, and wherein the upper member and the lower member are held substantially parallel by the at least two parallel flexure members.

7. The substrate gripper of claim 5, wherein the at least one flexure member comprises:
an upper flexure member coupling the distal member to the upper member; and
a lower flexure member coupling the distal member to the lower member, wherein at least one of the upper flexure member or the lower flexure member are configured to flex responsive to movement of the upper member with respect to the lower member.

8. The substrate gripper of claim 1, wherein the at least one flexure member elastically deforms without yielding responsive to movement of the second plate with respect to the first plate.

9. The substrate gripper of claim 1, wherein motion of the respective ends of the plurality of arms comprises an arc motion comprising a horizontal movement that is orthogonal to the movement of the second plate with respect to the first plate.

10. The substrate gripper of claim 1, wherein the substrate gripper is configured to be positioned above the substrate and to grip the substrate from above.

11. The substrate gripper of claim 10, further comprising:
a mounting member, wherein one of the first plate or the second plate is coupled with the mounting member, and wherein the mounting member is configured to catch particles to prevent the particles from falling onto the substrate.

12. A factory interface, comprising: a substrate-handling robot; and
a substrate gripper, wherein the substrate gripper comprises:
a first plate;
a second plate; and
a plurality of arms coupled with the first plate and the second plate, wherein each of the plurality of arms comprises at least one flexure member configured to flex responsive to movement of the second plate with respect to the first plate;
wherein flexure of the flexure members of the plurality of arms causes respective ends of the plurality of arms to perform a gripping action to grip a substrate.

13. The factory interface of claim 12, wherein the substrate gripper further comprises:
a plurality of gripping members, wherein each of the plurality of gripping members is coupled with a respective end of an arm of the plurality of arms, and wherein each of the plurality of gripping members is configured to pass through a slot formed in a substrate support that supports the substrate to grip an edge of the substrate.

14. The factory interface of claim 13, wherein the substrate-handling robot is configured to provide the substrate support supporting the substrate to the substrate gripper.

15. The factory interface of claim 12, wherein each of the plurality of arms comprises a distal member, an upper member, and a lower member, and wherein the distal member is coupled with at least one of the upper member or the lower member by the at least one flexure member.

16. The factory interface of claim 15, wherein the upper member is coupled to the lower member by at least two parallel flexure members, and wherein the upper member and the lower member are held substantially parallel by the at least two parallel flexure members.

17. The factory interface of claim 12, wherein the substrate gripper is configured to be positioned above the substrate and to grip the substrate from above.

18. A method, comprising:
providing, by a substrate-handling robot, a substrate support supporting a substrate to a substrate gripper;
actuating a plurality of arms of the substrate gripper, wherein each of the plurality of arms comprises at least one flexure member configured to flex responsive to actuation of the plurality of arms, and wherein flexure of the flexure members of the plurality of arms causes respective ends of the plurality of arms to perform a gripping action to grip the substrate; and
separating the substrate from the substrate support by the substrate gripper.

19. The method of claim 18, wherein the substrate gripper comprises a plurality of gripping members, wherein each of the plurality of gripping members is coupled with a respective end of an arms of the plurality of arms, and wherein each of the plurality of gripping members is configured to pass through a slot formed in the substrate support to grip an edge of the substrate.

20. The method of claim 18, further comprising:
transporting the substrate support, by the substrate-handling robot, to a first enclosure separate from the substrate; and
transporting the substrate, by the substrate-handling robot, from the substrate gripper to a second enclosure separate from the substrate support.
